(19) United States
(12) Patent Application Publication
(10) Pub. No.: US 2026/0068583 A1
(43) Pub. Date: Mar. 5, 2026

(54) SUBSTRATE PROCESSING APPARATUS, METHOD FOR MANUFACTURING A SEMICONDUCTOR DEVICE INCLUDING THE SAME, AND METHOD FOR MONITORING A SUBSTRATE SUPPORT DEVICE OF THE SUBSTRATE PROCESSING APPARATUS

(71) Applicant: Samsung Electronics Co., Ltd., Suwon-si (KR)

(72) Inventors: SUNG-CHAN KIM, Suwon-si (KR); Kihong KIM, Suwon-si (KR); KYUNGBEOM KIM, Suwon-si (KR); MIRA PARK, Suwon-si (KR); SUNG HONG PARK, Suwon-si (KR); YOUNGHOON SOHN, Suwon-si (KR); JONGJIN LEE, Suwon-si (KR); SUNG-IL CHOI, Suwon-si (KR)

(21) Appl. No.: 19/084,099

(22) Filed: Mar. 19, 2025

(30) Foreign Application Priority Data
Sep. 3, 2024 (KR) 10-2024-0119491

(51) Int. Cl. H01L 21/67

(52) U.S. Cl. CPC H01L 21/67115

(57) ABSTRACT

A substrate processing apparatus including a chamber, a substrate support platform provided inside the chamber, a lamp disposed at an upper portion of the chamber, and emitting light to an inside of the chamber, and a plate interposed between the lamp and the substrate support platform in the chamber, and including a plurality of holes through which the light, when emitted by the lamp, passes, wherein a surface of the substrate support platform is positioned to be irradiated with the light, and wherein for at least a first hole of the plurality of holes, a diameter of the hole becomes greater in a direction going downward from a top surface of the plate toward a bottom surface of the plate.

### CROSS-REFERENCE TO RELATED APPLICATIONS

This U.S. non-provisional patent application claims priority under 35 U.S.C. § 119 of Korean Patent Application No. 10-2024-0119491, filed on Sep. 3, 2024, the entire contents of which are hereby incorporated by reference.

### BACKGROUND

The present disclosure herein relates to a substrate processing apparatus, a method for manufacturing a semiconductor device including the same, and a method for monitoring a substrate support device of the substrate processing apparatus. More particularly, the monitoring method relates to a method for monitoring a surface discharge of the substrate support device of the substrate processing apparatus.

A semiconductor device may be manufactured through various processes. For example, the semiconductor device may be manufactured by performing a photo process, an etching process, a deposition process and a measuring process on a wafer such as a silicon wafer. A substrate such as the wafer may be fixed in the processes by a substrate support device. The substrate support device may support and/or fix the substrate to a surface of the substrate support device by using an electrostatic force. After the processes are completed for the substrate, an operation of discharging the surface of the substrate support device may be performed.

### SUMMARY

The present disclosure provides a method for monitoring a plate and a substrate support device for improving a surface discharge performance of the substrate support device.

The present disclosure also provides a method for manufacturing a semiconductor device with improved productivity and a method for monitoring the substrate support device of a substrate processing apparatus.

Technical goals of the inventive concept are not limited to the benefits mentioned above, and other technical goals that are not mentioned may be clearly understood from description below by those skilled in the art.

An embodiment of the inventive concept provides a substrate processing apparatus including a chamber, a substrate support platform provided inside the chamber, a lamp disposed at an upper portion of the chamber, and emitting light to an inside of the chamber, and a plate interposed between the lamp and the substrate support platform in the chamber, and including a plurality of holes through which the light, when emitted by the lamp, passes, wherein a surface of the substrate support platform is positioned to be irradiated with the light, and wherein for at least a first hole of the plurality of holes, a diameter of the hole becomes greater in a direction going downward from a top surface of the plate toward a bottom surface of the plate.

In an embodiment of the inventive concept, a substrate processing apparatus includes a chamber, a substrate support platform provided inside the chamber, a lamp disposed at an upper portion of the chamber, and emitting light to an inside of the chamber, and a plate interposed between the lamp device and the substrate support platform in the chamber, and including a plurality of holes through which the light is configured to pass, wherein the lamp is positioned to radiate light toward a surface of the substrate support device, the plate includes a reflection portion surrounded by the plurality of holes, and the reflection portion of the plate protrudes higher than any other region of the plate.

In an embodiment of the inventive concept, a method for monitoring a substrate support device includes supporting a substrate by a substrate support device provided in a chamber, performing a process on the substrate, detaching the substrate from the substrate support device, irradiating a surface of the substrate support device in the chamber with light emitted from a lamp device, measuring a voltage of the surface of the substrate support device after irradiating with the light, and generating an alarm in a case in which the voltage of the substrate support device is equal to or greater than a critical voltage, wherein the irradiating of a surface of the substrate support device with light emitted from a lamp device includes reflecting the light emitted from the lamp device off of a reflection portion of a plate, wherein the reflected light passes through holes of the plate, and irradiates the surface of the substrate support device, and at least one the holes, the diameter of the hole of the plate becomes greater in a direction going downward from a top surface of the plate toward a bottom surface of the plate.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view illustrating a substrate processing apparatus according to some embodiments of the inventive concept;

FIG. 2 is a perspective view illustrating a lamp device and a plate of a substrate processing apparatus according to some embodiments of the inventive concept;

FIG. 3 is a plan view illustrating a substrate support device of a substrate processing apparatus according to some embodiments of the inventive concept;

FIG. 4 is a cross-sectional view taken along line A-A′ of FIG. 3;

FIG. 5 is a cross-sectional view illustrating a substrate processing apparatus according to some embodiments of the inventive concept;

FIG. 6 is a flowchart of a method for manufacturing a semiconductor device according to some embodiments of the inventive concept; and

FIG. 7 is a flowchart of a method for monitoring a substrate support device of a substrate processing apparatus according to some embodiments of the inventive concept.

### DETAILED DESCRIPTION

Hereinafter, embodiments of the inventive concept will be described with reference to the accompanying drawings. The same reference numerals or symbols may refer to the same components throughout the entire specification.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

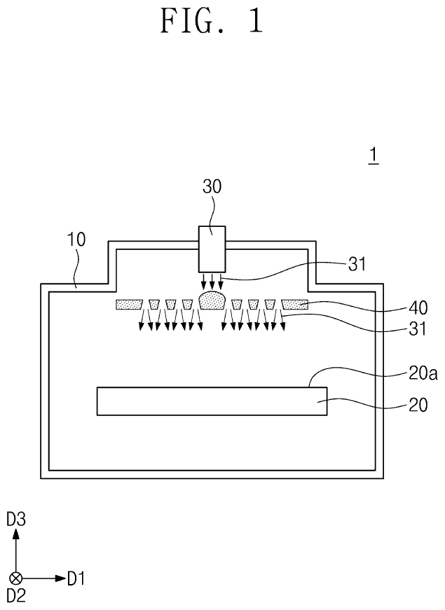

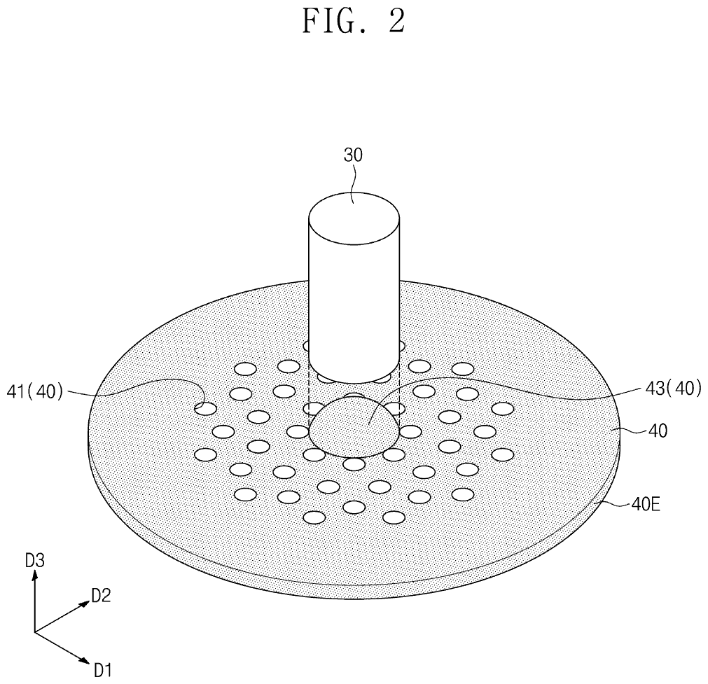

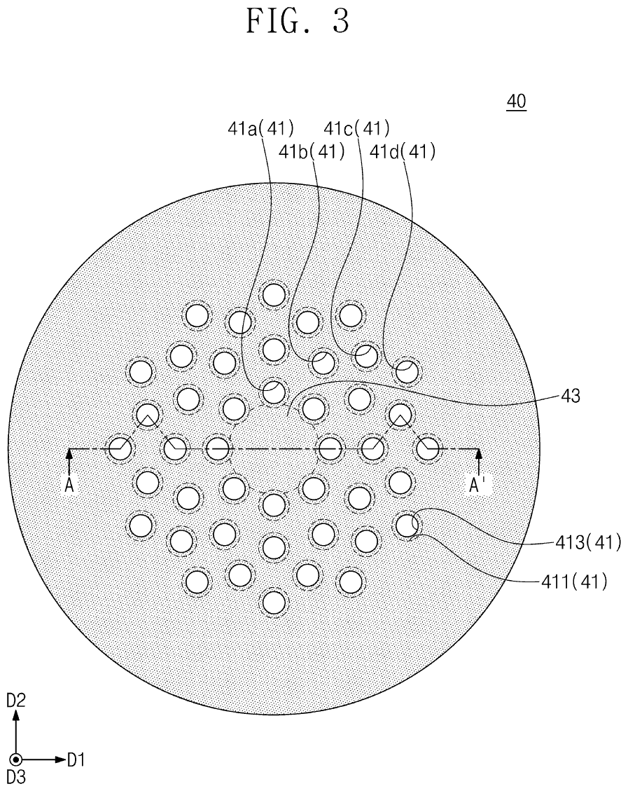

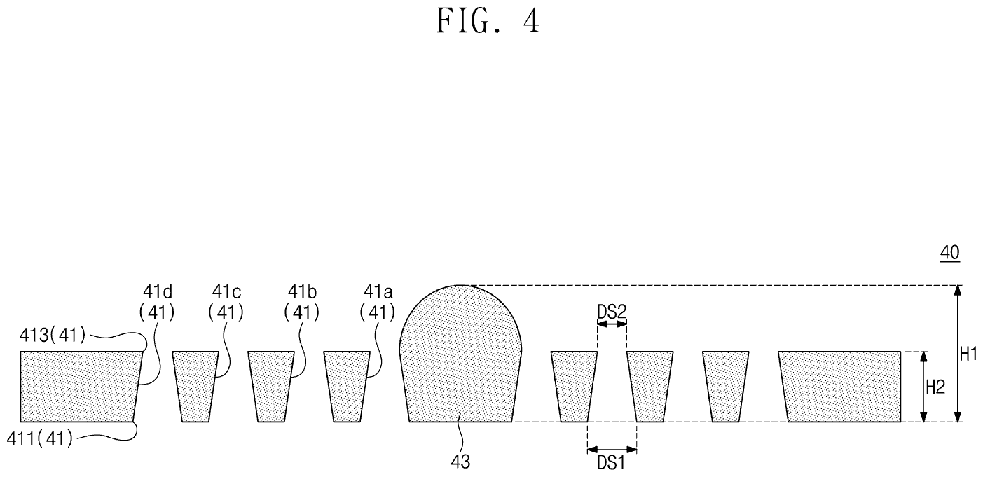

FIG. 1 is a cross-sectional view illustrating a substrate processing apparatus according to some embodiments of the inventive concept. FIG. 2 is a perspective view illustrating a lamp device and a plate of a substrate processing apparatus according to some embodiments of the inventive concept. FIG. 3 is a plan view illustrating a substrate support device of a substrate processing apparatus according to some embodiments of the inventive concept. FIG. 4 is a cross-sectional view taken along line A-A′ of FIG. 3.

Referring to FIGS. 1, 2, 3 and 4, a substrate processing apparatus 1 may be provided. The substrate processing apparatus 1 may be an apparatus that performs an etching process, a deposition process, or a measuring process on a substrate, for example. The substrate may be a silicon (Si) wafer, but embodiments of the inventive concept are not limited thereto. The substrate processing apparatus 1 may include a chamber 10, a substrate support device 20, a lamp device 30 and a plate 40.

The chamber 10 may provide an inner space inside a housing. A process on the substrate may be performed in the inner space of the chamber 10. The inner space of the chamber 10 may be connected to a vacuum pump (not shown). The vacuum pump may control an inner pressure of the chamber 10. For example, the inner space of the chamber 10 may be in a vacuum state by the vacuum pump.

The substrate support device 20 may be provided inside the chamber 10. Although not shown, the substrate support device 20 may be coupled to the lower portion of the chamber 10 through separate components to be fixed or movably secured. The substrate support device 20 may support and/or fix the substrate to a surface 20a of the substrate support device 20. For example, the surface 20a of the substrate support device 20 may be an upper surface of the substrate support device 20. For example, the surface 20a of the substrate support device 20 may be a surface of the substrate support device 20 irradiating with light 31 emitted from the lamp device 30 to be described later.

For example, the substrate support device 20 may be an electrostatic chuck (ESC) and may serve as a platform (e.g., a substrate support platform) on which to place a substrate such as a wafer. The substrate support device 20 may support and/or fix the substrate to the surface 20a of the substrate support device 20 by using an electrostatic force induced between the substrate support device 20 and the substrate. Specifically, a voltage may be applied to the inside of the substrate support device 20, and thus an electric field may be formed on the surface 20a of the substrate support device 20. As a result, electrostatic induction between the substrate support device 20 and the substrate may occur due to the electric field so that the electrostatic force therebetween operates to fix the substrate to the substrate support device 20 due to the electrostatic force.

Although not shown, a moving device (not shown) that moves a position of the substrate support device 20 may be provided under the substrate support device 20. The moving device may move the substrate support device 20 in a first direction D1 and a second direction D2. The first direction D1 and the second direction D2 may be each parallel to the surface 20a (e.g., an upper surface) of the substrate support device 20, and may cross each other.

The lamp device 30 may be provided in the chamber 10. Specifically, the lamp device 30 may be a lamp provided at an upper portion of the chamber 10. The lamp device 30 may emit light 31 to the inner space of the chamber 10. The light 31 may pass through holes 41 of the plate 40 to be described later such that the surface 20a of the substrate support device 20 is irradiated with the light 31. In this case, the substrate may be in a state of being detached from the substrate support device 20.

The light 31 emitted from the lamp device 30 may be a vacuum ultraviolet (VUV) ray. For example, the lamp device 30 may include a plasma lamp, a high-pressure mercury lamp, or the like. The lamp device 30 may include various components capable of emitting vacuum ultraviolet (VUV) light 31.

The surface 20a of the substrate support device 20 may be irradiated with the light 31 emitted by the lamp device 30 to discharge the surface 20a of the substrate support device 20. Specifically, after the substrate is detached from the substrate support device 20, a residual charge may remain on the surface 20a of the substrate support device 20. The surface 20a of the substrate support device 20 may be irradiated with the light 31 to remove the residual charge existing on the surface 20a of the substrate support device 20.

The plate 40 may be provided in the inner space of the chamber 10. The plate 40 may be adjacent to an upper portion of the chamber 10. Although not shown, the plate 40 may be coupled to the upper portion of the chamber 10 through separate components to be fixed or to be movably secured. The plate 40 may be interposed between the substrate support device 20 and the lamp device 30. For example, the plate may have a diameter of about 140 mm to about 360 mm.

The plate 40 may include a plurality of holes 41 through which the light 31 emitted from the lamp device 30 passes, and a reflection portion 43 surrounded by the holes 41. For example, the reflection portion 43 may not include holes such as the holes 41 thereinside. A thickness H2 of the other region of the plate 40 except for the reflection portion 43 of the plate 40 may be smaller than a thickness of the substrate support device 20. For example, a ratio of the thickness H2 of the other region of the plate 40 except for the reflection portion 43 of the plate 40 and the thickness of the substrate support device 20 may be about 1:3. A distance between adjacent ones of the holes 41 of the plate 40 may be about 1 mm to about 30 mm.

The reflection portion 43 of the plate 40 may vertically overlap the lamp device 30. Accordingly, the lamp device 30 may emit the light 31 toward the reflection portion 43 of the plate 40. The light 31 may be reflected and dispersed from the reflection portion 43 of the plate 40 in various directions, and the reflected and dispersed light 31 may pass through the holes 41 of the plate 40.

The reflection portion 43 of the plate 40 may be more protruding than any other region of the plate 40 in a third direction D3, and may be a reflection protrusion or a protruding portion. The reflection portion 43 may have a curved, convex shape as depicted in FIG. 4, but the shape of the reflection portion 43 is not limited thereto. The other region of the plate 40 is a region of the plate 40 except for the reflection portion 43 of the plate 40. The third direction D3 may be a direction perpendicular to the surface 20a (e.g., an upper surface) of the substrate support device 20. In some contexts of the present specification, the third direction D3 going away from the top surface of the plate 40 may be referred to as an upward direction, and an opposite direction of the third direction D3, for example going away from a bottom surface of the plate 40 may be referred to as a downward direction. A thickness H1 of the reflection portion 43 of the plate 40 may be greater than a thickness H2 of the other region of the plate 40. In some embodiments, an upper surface of the reflection portion 43 of the plate 40 may have a convex upward profile, but embodiments of the inventive concept are not limited thereto. The upper surface of the reflection portion 43 of the plate 40 may have different shapes so as to optimize reflection and dispersion of the light 31 emitted from the lamp device 30. In some embodiments, the thickness H1 of the reflection portion 43 of the plate 40 may be more than about 1 mm and equal to or less than about 10 mm. For example, the thickness H2 of the other region of the plate 40 except for the reflection portion 43 of the plate 40 may be less than the thickness H1 of the reflection portion 43 to be about 1 mm to about 5 mm.

According to aspects of the inventive concept, the reflection portion 43 of the plate 40 may be more protruding than the other region of the plate 40 in the third direction D3. Accordingly, the light 31 may be reflected and dispersed in more directions than when the light 31 is reflected by the reflection portion 43 having the upper surface having a flat profile. As a result, an amount of the light 31 moving to the holes 41 may increase. Finally, an amount of the light 31 with which the surface 20a of the substrate support device 20 is irradiated may increase by increasing the amount of the light 31 passing through the holes 41. Accordingly, a discharge performance for the substrate support device 20 may be improved.

A diameter of each of the holes 41 of the plate 40 may become greater in a direction moving downward (for example, in a direction from a top surface of the plate 40 toward a bottom surface of the plate 40). It is illustrated in the drawing that the diameters of all holes 41 have the above feature, but embodiments of the inventive concept are not limited thereto. At least one of diameters of the holes 41 of the plate 40 may have the above feature. A diameter DS1 of a lowermost end 411 of each of the holes 41 of the plate 40 may be greater than a diameter DS2 of an uppermost end 413. An inner surface of each of the holes 41 (or of at least one of the holes) of the plate 40 may have an inclined linear profile, and the inner surfaces of one or more of the holes may have a tapered shape in the direction from a bottom surface of the plate 40 toward the top surface of the plate 40. For example, a diameter of each of the holes 41 may be about 10 mm to about 30 mm. For example, the diameter DS1 of the lowermost end 411 of each of the holes 41 may be about 15 mm to about 40 mm. For example, the diameter DS2 of the uppermost end 413 of each of the holes 41 may be about 10 mm to about 30 mm. In some embodiments, the ratio of the diameter of the uppermost end of 413 of each tapered hole to the lowermost end 411 of each tapered hole may be between 1:4 and 3:4.

According to aspects of the inventive concept, the diameter of each of the holes 41 of the plate 40 may become greater in the direction going downward. Accordingly, the light 31 passing through the holes 41 having a diameter that becomes greater in the direction going downward may be dispersed more than the light 31 passing through the holes 41 having the vertically same (e.g., constant) diameter. As a result, the surface 20a of the substrate support device 20 may be evenly discharged (e.g., electrically discharged) by evenly irradiating the surface 20a of the substrate support device 20 with the light 31 passing through the holes 41 of the plate 40. Accordingly, the discharge performance for the substrate support device 20 may be improved.

The holes 41 of the plate 40 may be disposed in various methods. For example, the holes 41 of the plate 40 may include a set of first holes 41a that together surround the reflection portion 43 of the plate 40, a set of second holes 41b that together surround the first holes 41a, a set of third holes 41c that together surround the second holes 41b, and a set of fourth holes 41d that together surround the third holes 41c. Each of the first to fourth holes 41a, 41b, 41c and 41d may be disposed forming a circle, but embodiments of the inventive concept are not limited thereto. In addition, as illustrated in the drawing, the first to fourth holes 41a, 41b, 41c and 41d may be disposed in four columns, but embodiments of the inventive concept is not limited thereto. A disposition method and a disposition shape thereof may be variously changed by those skilled in the art so as to optimize passage of the light 31. In addition, as illustrated in the drawing, the plate 40 may include 44 holes 41, but embodiments of the inventive concept are not limited thereto. The number of the holes 41 may be selected by those skilled in the art so as to optimize passage of the light 31. In some embodiments, a distance between an edge portion 40E of the plate 40 and an outermost hole among the holes 41 may be about 1 mm to about 93 mm.

According to aspects of the inventive concept, the number of the holes 41 of the plate 40 may be large (to be 44 or greater than 44). Accordingly, the amount of the light 31 passing through the holes 41 of the plate 40 may increase, and thus the amount of the light 31 with which the surface 20a of the substrate support device 20 is irradiated may increase. In addition, since the holes 41 are formed in various regions inside the plate 40, the surface 20a of the substrate support device 20 may be evenly irradiated with the light 31 passing through the holes 41. Accordingly, the discharge performance for the substrate support device 20 may be improved.

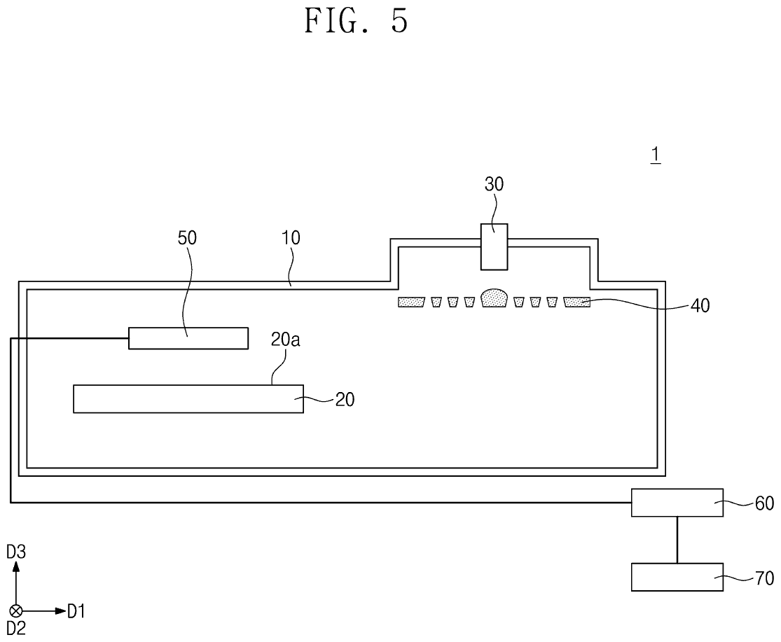

FIG. 5 is a cross-sectional view illustrating a substrate processing apparatus according to some embodiments of the inventive concept. Specifically, FIG. 5 is a cross-sectional view illustrating an operation of measuring a voltage of the surface 20a of the substrate support device 20 after discharging the surface 20a of the substrate support device 20 through the light 31 of the lamp device 30.

Referring to FIG. 5, the substrate processing apparatus 1 may include a first measuring device 50, a second measuring device 60, and an analysis device 70.

The first measuring device 50 may be provided inside the chamber 10. The substrate support device 20 may move under the first measuring device 50 through a moving device so as to measure the voltage of the surface 20a of the substrate support device 20. Accordingly, the first measuring device 50 may be provided on the surface 20a of the substrate support device 20.

The first measuring device 50 may perform measuring the voltage of the surface 20a of the substrate support device 20. For example, the first measuring device 50 may be a device that measures an electric potential charged on the surface 20a of the substrate support device 20. For example, the first measuring device 50 may be a surface potential meter (SPM), but embodiments of the inventive concept are not limited thereto. Although not shown, the first measuring device 50 may include a probe. The first measuring device 50 may measure the voltage of the surface 20a of the substrate support device 20 through the probe in a non-contact manner.

The second measuring device 60 may be connected to the first measuring device 50. It is illustrated in the drawing that the second measuring device 60 is provided outside the chamber 10, but embodiments of the inventive concept are not limited thereto. A position of the second measuring device 60 may be variously changed by those skilled in the art. The second measuring device 60 may process an electrical signal sensed by the probe of the first measuring device 50, and may change the electrical signal to a detected voltage (for example, the voltage of the surface 20a of the substrate support device 20). For example, the second measuring device 60 may be implemented with hardware and/or software such as a circuit or a computer program that converts a received signal from the surface potential meter to a voltage indication.

The analysis device 70 may be connected to the second measuring device 60. It is illustrated in the drawing that the analysis device 70 is provided outside the chamber 10, but embodiments of the inventive concept are not limited thereto. For example, the analysis device 70 may be implemented with hardware and/or software such as a circuit or a computer program configured to analyze data. The analysis device 70 may analyze data, related to the voltage of the surface 20a of the substrate support device 20, extracted from the second measuring device 60, and may visualize and provide the data to a worker. For example, when the voltage of the surface 20a of the substrate support device 20 is greater than a critical voltage, the analysis device 70 may include a separate alarm unit providing an alarm to the worker.

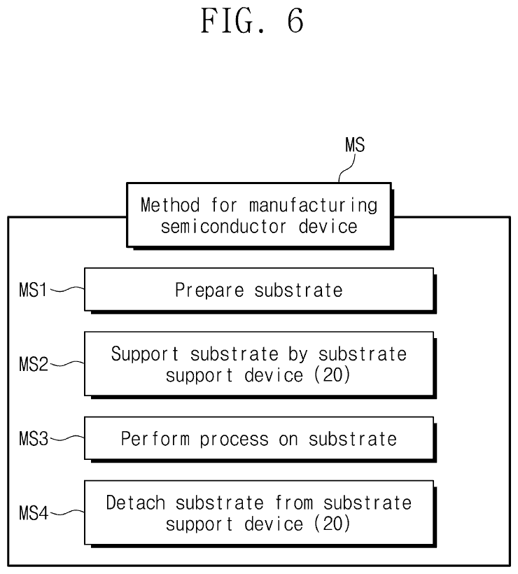

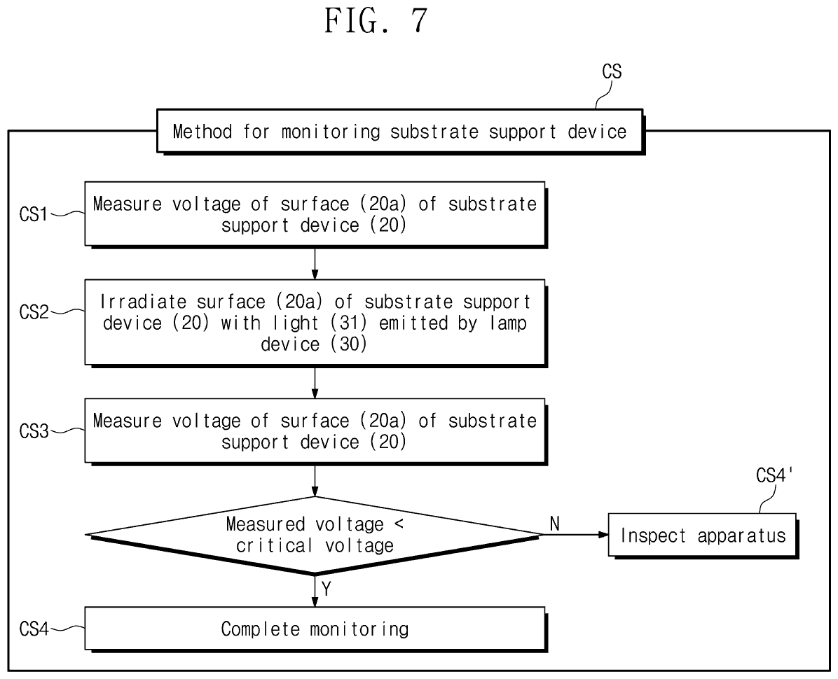

FIG. 6 is a flowchart of a method for manufacturing a semiconductor device according to some embodiments of the inventive concept. FIG. 7 is a flowchart of a method for monitoring a substrate support device of a substrate processing apparatus according to some embodiments of the inventive concept.

Referring to FIGS. 5 and 6, a method (MS) for manufacturing a semiconductor device may be a method for manufacturing a semiconductor device by using a substrate. The method (MS) for manufacturing a semiconductor device may include an operation (MS1) of preparing a substrate, an operation (MS2) of supporting the substrate by the substrate support device 20, an operation (MS3) of performing a process on the substrate and an operation (MS4) of detaching the substrate from the substrate support device 20.

For example, the operation (MS1) of preparing a substrate may include an operation of preparing the substrate undergoing some of the processes of manufacturing the semiconductor device. For example, more specifically, the operation (MS1) of preparing a substrate may include an operation of preparing a semiconductor wafer undergoing a photo process, a deposition process, a develop process, or the like before a measuring process.

For example, the operation (MS2) of supporting the substrate to the substrate support device 20 may include an operation of moving the substrate to the substrate support device 20 through a separate moving robot, and supporting the substrate to the substrate support device 20 by using an electrostatic force.

For example, the operation (MS3) of performing a process on the substrate may include an operation of performing not only an etching process and a deposition process but also a measuring process on the substrate.

Referring to FIGS. 4, 5, and 6, an operation of monitoring the substrate support device 20 may be performed after the operation (MS4) of detaching the substrate from the substrate support device 20.

A method (CS) for monitoring the substrate support device 20 may include a first operation (CS1) of measuring a voltage of the surface 20a of the substrate support device 20, a second operation (CS2) of irradiating the surface 20a of the substrate support device 20 with the light 31 emitted by the lamp device 30, a third operation (CS3) of measuring the voltage of the surface 20a of the substrate support device 20 after irradiating the surface 20a of the substrate support device 20, and a fourth operation (CS4) of completing the monitoring in a case in which the voltage measured in the third operation (CS3) is smaller than a critical voltage. The method (CS) for monitoring the substrate support device 20 may further include an operation (CS4′) of inspecting the apparatus in a case in which the voltage measured in the third operation (CS3) is equal to or greater than the critical voltage. After the fourth operation (CS4), the method (MS) for manufacturing a semiconductor device may be performed again.

For example, before performing the first operation (CS1), the substrate support device 20 may move from under the plate 40 to under the first measuring device 50 by a moving unit.

The first operation (CS1) may include an operation of measuring the voltage of the surface 20a of the substrate support device 20 through the first measuring device 50 and the second measuring device 60. Specifically, as illustrated above, the second measuring device 60 may measure the voltage of the surface 20a of the substrate support device 20 by processing the electrical signal sensed by the probe of the first measuring device 50, and changing the electrical signal to the voltage. For example, voltages of a plurality of regions of the surface 20a of the substrate support device 20 may be measured through the first measuring device 50 and the second measuring device 60. The first operation (CS1) may include an operation of analyzing the measured voltage data through the analysis device 70, and visualizing and providing the data to the worker.

For example, after performing the first operation (CS1) and before performing the second operation (CS2), the substrate support device 20 may move from under the first measuring device 50 to under the plate 40 through the moving unit.

The second operation (CS2) may further include an operation of the light 31 emitted by the lamp device 30 passing through the holes 41 of the plate 40. The surface 20a of the substrate support device 20 may be discharged through the second operation (CS2).

For example, after performing the second operation (CS2) and before performing the third operation (CS3), the substrate support device 20 may move from under the plate 40 to under the first measuring device 50 by the moving unit. The third operation (CS3) may be performed in the same measuring manner as or a similar measuring manner to the first operation (CS1).

When the voltage of the surface 20a of the substrate support device 20 measured through the third operation (CS3) is smaller than the critical voltage, the fourth operation (CS4) may be performed. For example, a value of the voltage may be an average of the voltages of the surface 20a of the substrate support device 20 measured through the third operation (CS3). For example, a value of the critical voltage may be a positive number.

When the voltage of the surface 20a of the substrate support device 20 measured through the third operation (CS3) is equal to or greater than the critical voltage, the operation (CS4′) of inspecting the apparatus may be performed. For example, the operation (CS4′) of inspecting the apparatus may include an operation of performing at least one of replacing or cleaning the substrate support device 20, replacing or cleaning the lamp device 30, replacing or cleaning the plate 40, or additionally performing the second operation (CS2), but an embodiment of the inventive concept is not limited thereto.

When the voltage of the surface 20a of the substrate support device 20 measured through the third operation (CS3) is equal to or greater than the critical voltage, an alarm may be provided to a worker through a separate alarm unit before the operation (CS4′) of inspecting the apparatus.

According to aspects of the inventive concept, the voltage measured in the third operation (CS3) may be controlled to be smaller than the critical voltage by performing the method (CS) for monitoring the substrate support device described above. Accordingly, a substrate sticking phenomenon caused by a charge remaining on the surface 20a of the substrate support device 20 when the substrate is detached from the substrate support device 20 may be reduced. As a result, a substrate jumping phenomenon and a substrate breaking phenomenon caused by the substrate sticking phenomenon may be reduced. Accordingly, productivity of the substrate processing apparatus 1 and the method (MS) for manufacturing a semiconductor device may be improved.

In addition, when a discharge performance for the surface 20a of the substrate support device 20 is deteriorated, a number of times that the second operation (CS2) is performed may increase. Since aspects of the inventive concept have features of the plate 40 described above, the discharge performance for the surface 20a of the substrate support device 20 may be improved. Accordingly, the second operation (CS2) may not be unnecessarily performed many times. Accordingly, productivity of the substrate processing apparatus 1 and the method (MS) for manufacturing a semiconductor device may be improved.

According to aspects of the inventive concept, a reflection portion of a plate may protrude higher than any other region of the plate. Accordingly, light may be reflected and dispersed in more directions than when the light is reflected and dispersed by the reflection portion having an upper surface having a flat profile. As a result, an amount of the light moving to holes of the plate may increase. Finally, an amount of the light with which a surface of a substrate support device is irradiated may increase by increasing the amount of the light passing through the holes of the plate. Accordingly, a discharge performance for the substrate support device may be improved.

According to aspects of the inventive concept, a diameter of each of the holes of the plate may become greater in a direction going downward. Accordingly, the light passing through the holes having the diameter that becomes greater in the direction going downward may be dispersed more than the light passing through the holes having the vertically same diameter. As a result, the surface of the substrate support device may be evenly discharged by evenly irradiating the surface of the substrate support device with the light passing through the holes of the plate. Accordingly, the discharge performance for the substrate support device may be improved.

According to aspects of the inventive concept, a number of the holes of the plate may increase. Accordingly, the amount of the light passing through the holes of the plate may increase, and thus the amount of the light with which the surface of the substrate support device is irradiated may increase. In addition, since the holes are formed in various regions inside the plate, the surface of the substrate support device may be evenly irradiated with the light passing through the holes. Accordingly, the discharge performance for the substrate support device may be improved.

According to aspects of the inventive concept, a voltage measured on a surface of the substrate support device may be controlled to be smaller than a critical voltage by performing a method for monitoring the substrate support device. Accordingly, a substrate sticking phenomenon caused by a charge remaining on the surface of the substrate support device when the substrate is detached from the substrate support device may be reduced. As a result, a substrate jumping phenomenon and a substrate breaking phenomenon caused by the substrate sticking phenomenon may be reduced. Accordingly, productivity of a substrate processing apparatus and a method for manufacturing a semiconductor device may be improved.

In addition, when a discharge performance for the surface of the substrate support device is deteriorated, a number of times that the surface of the substrate support device is irradiated with the light may increase. Since aspects of the inventive concept have features of the plate described above, the discharge performance for the surface of the substrate support device may be improved. Accordingly, the number of times that the surface of the substrate support device is irradiated with the light may not unnecessarily increase. Accordingly, productivity of the substrate processing apparatus and the method for manufacturing a semiconductor device may be improved.

The above description of embodiments of the inventive concept provides an example for description of the inventive concept. Therefore, the inventive concept is not limited to the above embodiments, and various modifications and changes such as combining the above embodiments may be made by those skilled in the art within the technical spirit of the inventive concept.

1. A substrate processing apparatus comprising:
a chamber;
a substrate support platform provided inside the chamber;
a lamp disposed at an upper portion of the chamber, and configured to emit light to an inside of the chamber; and
a plate interposed between the lamp and the substrate support platform in the chamber, and including a plurality of holes through which the light, when emitted by the lamp, passes,
wherein a surface of the substrate support platform is positioned to be irradiated with the light, and
wherein for at least a first hole of the plurality of holes, a diameter of the hole becomes greater in a direction going downward from a top surface of the plate toward a bottom surface of the plate.

2. The substrate processing apparatus of claim 1, wherein:
the plate comprises a reflection portion surrounded by the plurality of holes, and
the reflection portion of the plate vertically overlaps the lamp.

3. The substrate processing apparatus of claim 2, wherein an upper surface of the reflection portion of the plate has a convex upward profile.

4. The substrate processing apparatus of claim 2, wherein the reflection portion of the plate protrudes higher than any other region of the plate.

5. The substrate processing apparatus of claim 2, wherein the reflection portion of the plate has a greater thickness in a vertical direction than any other region of the plate.

6. The substrate processing apparatus of claim 2, wherein the reflection portion of the plate does not include any of the plurality of the holes.

7. The substrate processing apparatus of claim 1, wherein lowermost ends of the holes of the plate have a greater diameter than uppermost ends of the holes of the plate.

8. The substrate processing apparatus of claim 1, wherein the light of the lamp is vacuum ultraviolet (VUV) light.

9. The substrate processing apparatus of claim 1, wherein the radiated light is configured to discharge the surface of the substrate support platform.

10. The substrate processing apparatus of claim 1, wherein the plurality of holes comprise first holes, second holes surrounding the first holes, third holes surrounding the second holes, and fourth holes surrounding the third holes.

11. A substrate processing apparatus comprising:
a chamber;
a substrate support platform provided inside the chamber;
a lamp disposed at an upper portion of the chamber, and configured to emit light to an inside of the chamber; and
a plate interposed between the lamp and the substrate support platform in the chamber, and including a plurality of holes through which the light is configured to pass,
wherein the lamp is positioned to radiate light toward a surface of the substrate support platform,
wherein the plate includes a reflection portion surrounded by the plurality of holes, and
wherein the reflection portion of the plate protrudes higher than any other region of the plate.

12. The substrate processing apparatus of claim 11, wherein an upper surface of the reflection portion of the plate has a convex upward profile.

13. The substrate processing apparatus of claim 11, wherein the reflection portion of the plate has a greater thickness in a vertical direction than any other region of the plate.

14. The substrate processing apparatus of claim 11, wherein a diameter of each of the holes of the plate becomes greater in a direction going downward from a top surface of the plate toward a bottom surface of the plate.

15. The substrate processing apparatus of claim 11, wherein the light of the lamp is vacuum ultraviolet (VUV) light.

16. The substrate processing apparatus of claim 11, wherein the light radiated toward the surface of the substrate support platform is configured to discharge the surface of the substrate support device.

17. The substrate processing apparatus of claim 11, wherein the plurality of holes comprise first holes surrounding the reflection portion, second holes surrounding the first holes, third holes surrounding the second holes, and fourth holes surrounding the third holes.

18. A method for monitoring a substrate support device, the method comprising:
supporting a substrate by a substrate support device provided in a chamber;
performing a process on the substrate;
detaching the substrate from the substrate support device;
irradiating a surface of the substrate support device in the chamber with light emitted from a lamp device;
measuring a voltage of the surface of the substrate support device after irradiating with the light; and
generating an alarm in a case in which the voltage of the substrate support device is equal to or greater than a critical voltage,
wherein the irradiating of a surface of the substrate support device with light emitted from a lamp device includes reflecting the light emitted from the lamp device off of a reflection portion of a plate, wherein the reflected light passes through holes of the plate, and irradiates the surface of the substrate support device, and
wherein for at least one the holes, the diameter of the hole of the plate becomes greater in a direction going downward from a top surface of the plate toward a bottom surface of the plate.

19. The method of claim 18, wherein the light is vacuum ultraviolet (VUV).

20. The method of claim 18, wherein:
the plate further comprises a reflection portion surrounded by the holes, and
the reflection portion of the plate protrudes higher than any other region of the plate.
